(19) United States
(12) Patent Application Publication
(10) Pub. No.: US 2012/0129347 A1
(43) Pub. Date: May 24, 2012

(54) Apparatus and Method For Incorporating Composition Into Substrate Using Neutral Beams

(76) Inventors: Geun-Young Yeom, Seoul (KR); Byoung-Jae Park, Gyeryoung-si (KR); Sung-Woo Kim, Seoul (KR)

(21) Appl. No.: 13/293,953

(22) Filed: Nov. 10, 2011

Related U.S. Application Data
(63) Continuation-in-part of application No. 12/031,540, filed on Feb. 14, 2008, now abandoned.

(30) Foreign Application Priority Data
Feb. 11, 2008 (KR) 2008-0012135

(51) Int. Cl. H01L 21/31

(52) U.S. Cl. 438/694; 257/E21.24

(57) ABSTRACT

An apparatus and method for processing a surface of a substrate using neutral beams are provided to repeatedly process an oxide layer using the neutral beams having low energy to minimize electrical damage to the oxide layer and improve characteristics of the oxide layer. The apparatus is mounted in a plasma generating chamber, and includes: an ion beam generating gas inlet, which injects a gas for generating ion beams; an ion source, which generates the ion beams having a polarity from the gas introduced through the ion beam generating gas inlet; a grid assembly, which is installed on one end of the ion source; a reflector, which is aligned with the grid assembly and converts the ion beams to the neutral beams; and a stage, on which the substrate is placed on a traveling path of the neutral beams.

### CROSS-REFERENCE TO RELATED APPLICATION

This application is a continuation-in-part of U.S. application Ser. No. 12/031,540 filed on Feb. 14, 2008 which claims priority to and the benefit of Korean Patent Application No. 2008-0012135, filed Feb. 11, 2008, the disclosure of which is hereby incorporated herein by reference in its entirety.

### FIELD OF THE INVENTION

The present invention relates to an apparatus and method for processing a surface of a substrate using neutral beams in order to improve characteristics of the substrate, and more particularly, to an apparatus and method for processing a surface of a substrate using neutral beams, in which formation of an oxide layer and application of the neutral beams are repeatedly performed twice or more on the substrate to be processed, thereby increasing uniformity of the applied neutral beams.

### BACKGROUND OF THE INVENTION

With high integration of semiconductor devices, the area of a memory cell is being reduced. This acts as a serious obstacle to increasing the integration of a non-volatile memory device having a plurality of cell transistors.

Thus, a silicon-oxide-nitride-oxide-silicon (SONOS) non-volatile memory device, which has a single gate electrode as in a metal oxide semiconductor field effect transistor (MOSFET) and can trap electric charges, has been proposed. The SONOS non-volatile memory device has advantages in that it can be easily fabricated and it can be easily integrated with a peripheral region or a logic region of an integrated circuit.

FIG. 1 is a cross-sectional view illustrating the structure of a conventional SONOS device.

As illustrated in FIG. 1, the SONOS device includes a lower insulating layer 130, a charge storage layer 140, an upper insulating layer 150, and a gate electrode, which are sequentially staked on a substrate 110 having an isolation layer 120. At this time, the lower and upper insulating layers 130 and 150 are formed of a silicon oxide (SiO₂) layer using chemical vapor deposition, and the charge storage layer 140 is formed of a silicon nitride (Si₃N₄) layer.

The SONOS device having this structure is a floating trap memory device rather than a floating gate memory device that is a flash memory device, and performs a program operation in a manner such that electric charges are stored in the charge storage layer 140, formed of a nitride layer, between the lower and upper insulating layers 130 and 150.

However, since the nitride layer used as the charge storage layer 140 has a too small trap site, many electric charges are not stored in the nitride layer. Therefore, the program operation for storing the electric charges in the trap site and the erase operation for eliminating the electric charges are reduced in speed.

Thus, in order to maximize performance of the non-volatile memory device, charge trap flash (CTF) technology, which makes use of a metal layer or a charge blocking layer which has a high work function as the gate electrode and of a high-k dielectric layer, is employed.

For example, a tantalium-aluminium oxide-nitride-oxide-silicon (TANOS) or silicon-aluminium oxide-nitride-oxide-silicon (SANOS) non-volatile memory device, which makes use of a TaN layer as the gate electrode and an aluminum oxide layer as a high-k dielectric layer, has been proposed.

### BRIEF SUMMARY OF THE INVENTION

The present invention provides an apparatus and method for processing a surface of a substrate using neutral beams, in which the neutral beams are applied to an oxide layer twice or more so as to be uniformly applied to the substrate to be processed.

The present invention also provides an apparatus and method for processing a surface of a substrate using neutral beams, in which the neutral beams are uniformly applied to an oxide layer, thereby performing efficient composition incorporation on a next-generation semiconductor device.

The present invention also provides an apparatus and method for processing a surface of a substrate using neutral beams, in which the neutral beams having low energy are applied to an oxide layer formed on the substrate to be processed, thereby preventing the oxide layer from being etched, minimizing damage to the oxide layer, and preventing surface diffusion caused by post treatment such as heat treatment.

In other words, the present invention is different from known ion incorporation in that the neutral beams are used within an energy range in which the oxide layer is hardly etched. An apparatus for this ion incorporation accelerates ionized dopants at a high speed, and thereby incorporates the accelerated dopants into a surface of the substrate. In a semiconductor fabrication process, the ion incorporation is to endow atomic ions having electrical characteristics with enough energy enough to penetrate the surface of the substrate, and incoporate the atomic ions into the substrate, i.e., the non-conductor, without change of the thickness of substrate.

According to one aspect of the present invention, there is provided an apparatus for processing a surface of a substrate using neutral beams, which is mounted in a plasma generating chamber. The apparatus includes: an ion beam generating gas inlet, which injects a gas for generating ion beams; an ion source, which generates the ion beams having a polarity from the gas introduced through the ion beam generating gas inlet; a grid assembly, which is installed on one end of the ion source; a reflector, which is aligned with the grid assembly and converts the ion beams to the neutral beams; and a stage, on which the substrate is placed on a traveling path of the neutral beams. Formation of the oxide layer and application of the neutral beams are repeatedly performed on the substrate so as to improve characteristics of the oxide layer.

Here, the characteristics of the oxide layer may be improved by processing the oxide layer using the neutral beams having a low energy below 100 eV such that there is almost no change in thickness of the oxide layer.

Further, the characteristics of the oxide layer may be improved by processing the oxide layer using the neutral beams having a low energy of 10 eV.

Also, the gas introduced through the ion beam generating gas inlet may include one selected from the group consisting of nitrogen series, oxygen series, CₓF_{y} series, and fluorine series.

Meanwhile, the substrate may be formed of SiO₂, and electrical characteristics of a gate oxide layer may be improved by incorporation using the neutral beams.

Further, the substrate may be formed of a high-k material such as Al₂O₃, HfO₂, TiO₂, ZrO₂, Y₂O₃, Ta₂O₅, BeO or La₂O₃, and electrical characteristics of the oxide layer may be improved by incorporation using the neutral beams.

In addition, one of a silicon-oxide-nitride-oxide-silicon (SONOS) structure, a tantalium-aluminium oxide-nitride-oxide-silicon (TANOS) structure and a silicon-aluminium oxide-nitride-oxide-silicon (SANOS) structure is formed on the substrate.

According to another aspect of the present invention, there is provided a method of processing a surface of a substrate using neutral beams. The method includes: (a) forming an oxide layer on the substrate; and applying the neutral beams to the oxide layer to incorporate at least one of O, N and F elements into the oxide layer, wherein the neutral beams are generated through the steps of: injecting a gas including at least one of O₂, N₂, C_{X}F_{Y} (where x=1 to 4, y=2 to 8) and NF₃ for generating ion beams through an inlet into an ion source; generating the ion beams having a polarity from the injected gas in the ion source; and converting the ion beams to neutral beams at least one of O, N and F elements. The step (a) and (b) may be repeated at least one time

### BRIEF DESCRIPTION OF THE DRAWINGS

The above and other advantages of the present invention will become readily apparent by reference to the following detailed description when considered in conjunction with the accompanying drawings wherein:

FIG. 1 is a cross-sectional view illustrating the structure of a conventional silicon-oxide-nitride-oxide-silicon (SONOS) device;

FIG. 2 is a cutaway exploded perspective view of an apparatus for processing a surface of a substrate using neutral beams according to the present invention;

FIG. 3 illustrates the state in which the apparatus for processing a surface of a substrate using neutral beams illustrated in FIG. 2 is mounted in a plasma generating chamber;

FIG. 4 is a graph showing the results obtained by measuring a change in the depth profile of an oxide layer using secondary ion mass spectrometry (SMIS) after a target substrate is subjected to surface treatment by the apparatus illustrated in FIG. 3;

FIG. 5 is a graph showing characteristics of a memory fabricated using the apparatus for processing a surface of a substrate using neutral beams according to the present invention;

FIG. 6 illustrates a conventional process of processing a substrate using neutral beams; and

FIG. 7 is a schematic cross-sectional view illustrating a process of forming an oxide layer on a target substrate and a process of applying neutral beams to the oxide layer using the apparatus for processing a surface of a substrate using neutral beams according to the present invention.

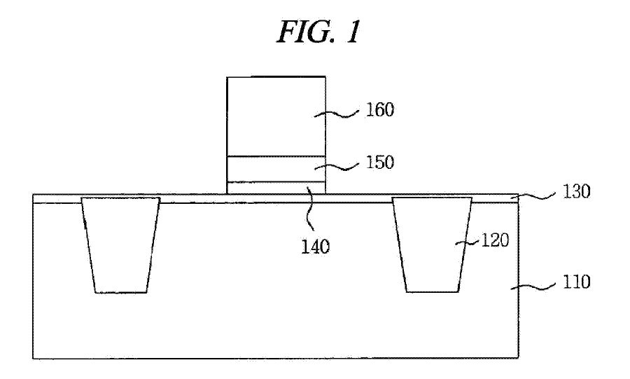

### DETAILED DESCRIPTION OF THE INVENTION

Hereinafter, the present invention will be explained in detail with reference to the accompanying drawings.

First, the configuration of an apparatus for implementing a method of processing a surface of a substrate using neutral beams according to the present invention will be described with reference to the accompanying drawings.

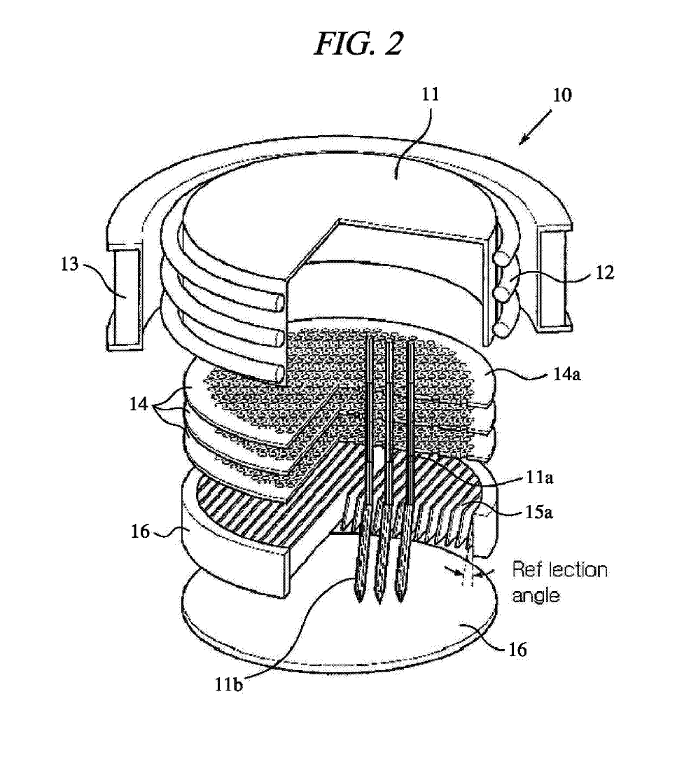

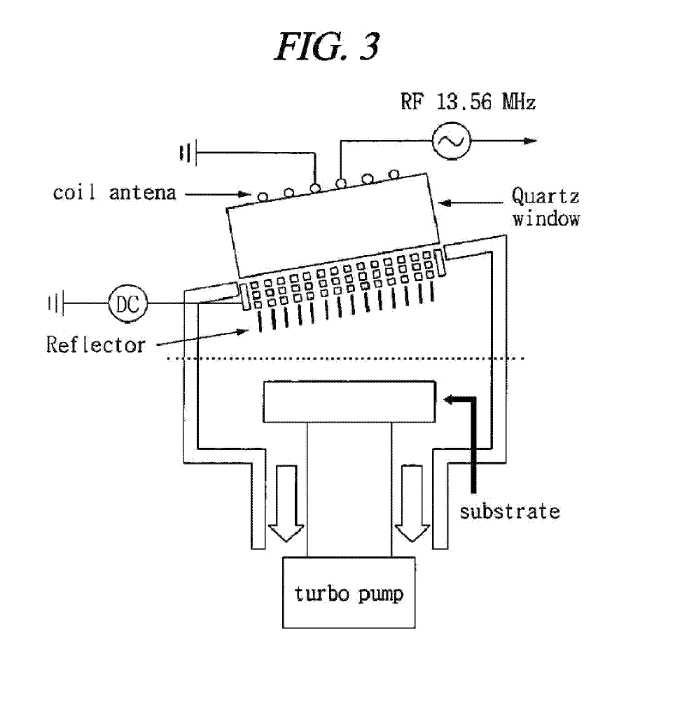

FIG. 2 is a cutaway exploded perspective view of an apparatus for processing a surface of a substrate using neutral beams according to the present invention. FIG. 3 illustrates the state in which the apparatus for processing a surface of a substrate using neutral beams illustrated in FIG. 2 is mounted in a plasma generating chamber.

The apparatus 10 for processing a surface of a substrate using neutral beams according to the present invention includes an ion source 11, an induction coil 12, an electromagnet 13, a grid assembly 14, and a reflector 15.

Here, the ion source 11 may extract and accelerate ion beams 11a having a predetermined polarity, and the induction coil 12 is wound around the ion source 11.

The electromagnet 13 applies an electromagnetic field to the induction coil 12. The grid assembly 14 is located under the ion source 11, and has three grids, each of which is provided with a plurality of grid holes 14a through which the ion beams 11a passes.

The reflector 15 is in close contact with the grid assembly 14, and has a plurality of reflecting plates 15a corresponding to the grid holes 14a of the grid assembly 14. The reflector 15 reflects the ion beams 11a, which pass through the grid holes 14a, onto the reflecting plates 15a, and converts the reflected ion beams to neutral beams 11b.

Further, the composition incorporating apparatus 10 includes a stage, on which a substrate 16 to be processed (hereinafter, referred to as a “target substrate”), a wafer, may be positioned on a traveling path of the neutral beams 11b.

Preferably, a retarding grid is additionally installed between the reflector 15 and the stage so as to control directionality and accelerating energy of the neutral beams 11b. A diameter of the reflecting plate 15a may be constructed to be equal to or greater than a diameter of each grid hole 14a.

Further, the grid assembly 14 has a cylindrical shape, and is provided with protrusions along an outer circumferential edge of the bottom surface thereof. The reflector 15 has a cylindrical shape, and is provided with protrusions, which may be inserted into the respective protrusions of the grid assembly 14, along an outer circumferential edge of the top surface thereof.

Furthermore, the reflecting plates 15a are inclined to the direction, in which the ion beams 11a travel straight through the grid holes 14a, at a predetermined angle, such that the ion beams 11a are reflected from the reflecting plates 15a.

Here, the reflecting plates 15a of the reflector 15 may be arranged to be inclined to the central axis of the reflector 15 at a predetermined angle or to be parallel to the central axis of the reflector 15. The protrusions of the reflector 15, which are formed along the outer circumferential edge of the top surface of the reflector 15, may be constructed to be inclined at a predetermined angle.

According to the present invention, the ion source 11 includes various types of ion sources. The reflector 15 is formed of a semiconductor substrate, a silicon dioxide or metal substrate, or a graphite substrate. Each ion beam 11a, which is incident through the grid holes 14a of the grid assembly 14, may be constructed at an incident angle from 5 to 15 degrees.

In the present invention, the ion source 11 may generate the ion beams 11a, and the reflector 15 is installed between the ion source 11 and the stage on which the target substrate 16, the wafer, is placed, so as to reflect the ion beams 11a having a predetermined incident angle. Thereby, the neutral beams 11b may be obtained.

The term “neutral beam” in the present invention means a beam in an electrically neutral state, which is artificially produced to control directivity and energy thereof. In this regard, directivity and energy of ion beam are controlled in a grid while a controlled ion accepts an electron in a reflection plate to produce an electrically neutral beam. The electrically neutral beam is irradiated to a substrate to proceed various processes.

Positive ions are extracted from a high-density plasma source using a three-grid system, and the positive ions being deficient in electrons receive electrons via an ion-electron charge exchange collision phenomenon in the reflection plate which is inclined at an angle of about 5°, resulting in a formation of an neutral beams in an electrically neutral state (US Publication Patent No. 2002060201). The grid system may be included two grids or three grids, and the three-grids system is currently used because the three-grid system is excellent in an aspect of beam flux with respect to energy.

Properties of the ion beams extracted are settled by applying a voltage in the three-grid system as follow:

a positive voltage is applied to first grid (acceleration grid), which determines the energy of the beam;

a negative voltage is applied to second grid (exraction grid), which controls the beam optic by electric field; and

a third grid is in a state of ground.

In process of conventional semi-conductors, HDP (High Density Plasma) is typically used for etching process of micro-pattern. During the etching process, high density ions having energy from a few tens to a few hundreds eV are irradiated to a substrate for an anistropic etching (Kin P. Cheung, Plsma Charging Damage, Springer-Verlag London Berlin Heidelberg, 2000).

However, when such high density ions are irradiated to the substrate, there are not only electric and physical damages but also other complex problems such as loading problem, stringer, sidewall residue and the like by reactive radicals and a fixed sheath geometry.

Although such damages in the conventional semiconductor devices can be controlled by methods such as annealing or removal of surface layer, it is expected that the methods may not remove the damages in the future semiconductor devices because of thermal weakness and very-thin layer.

Therefore, a neutral beam is qualified as the best way to solve such problems.

The ion-electron charge exchange collision used in the present invention is a neutralizing method by interaction between ion particles and solid surface.

In order to neutralize an ion, it is required a binding with an electron, in which is physically impossible that an ion solely bonds with an electron for neutralization. Therefore, in the ion-electron charge exchange collision, three body recombination method using a surface acting as a medium is used to neutralizing an ion.

In other words, in case of the two body recombination method, one body is formed from two body as in the following reaction equation (i), in which energy and momentum are not preserved in a gas state:

e+A⁺→A (i)

However, in the three body recombination method, most of positive ions having 10˜1000 V of energy are neutralized in surface by a very rapid three body neutralization reaction as in the following reaction equation (ii):

e+A⁺+S→A+S (ii)

Such ion-neutral charge exchange collision method is distinguished into a single grid structure, and a structure of grid and reflection plate according to its structure. In the single grid structure, the extraction and neutralization of ions is simultaneously achieved by using a single grid. In the structure of grid and reflection plate used in the present invention, each of extraction and neutralization of ions are separately achieved by using the grid and the reflection plate.

The ion-neutral charge exchange collision method includes process that incident ions are collided with the surface of a material and then reflected. The process may be explained by three of “incoming process”, “collision process” and “reflection process” as follow:

When an ion is close to the surface of a material, an electron is overlapped prior to the collision between atomic nuclei, resulting in a charge exchange.

Further, an auger process is occurred in this process. Then, an electron is excited by the collision between incident ions or neutralized ions with the atomic nuclei. The incident ions are reflected and reacted again with an electron.

Further, when outgoing particles are ions, an attachment of an electron on the surface is occurred. The attached electron includes a secondary electron or auger electron having a low energy which is generated in the collision (Rabalais, J. W., Principles and Applications of Ion Scattering Spectrometry: Surace Chemical and Structural Analysis, John Wiley and Sons, Inc., New Jersey (2003)).

Such neutralizing process is mainly occurred in a range of from about 1 eV to about 500 eV (Rabalais, J. W., Principles and Applications of Ion Scattering Spectrometry: Surace Chemical and Structural Analysis, John Wiley and Sons, Inc., New Jersey (2003)).

When an energy of the incident ions is higher than 1 kV, the particles move faster than a time required for the charge exchange, and collided with the atomic nuclei, resulting in sputtering or implatation.

In order words, according to the present invention, the neutral beams are used as an ion incorporation source for processing a surface of the substrate, so that electrical characteristics can be improved in a next generation device such as a tantalium-aluminium oxide-nitride-oxide-silicon (TANOS) device, a silicon-aluminium oxide-nitride-oxide-silicon (SANOS) device, etc. without causing electrical and physical damages to the target substrate 16 due to the ion beam as in the prior art.

SONOS, TANOS, and SANOS are the next generation of a flash memory structure to improve problems of the conventional floatin gate (FG).

A TANOS device includes TaN (TiN may be used as a gate electrode)—Al₂O₃ (a blocking oxide layer)—Si₃N₄ (a charge trapping layer)—SiO₂ (a tunnel oxide layer)—Si (a substrate) structure, and TANOS means a combination of the first letter of the each of the above thin layers. SONOS includes poly-Si as a gate electrode, and SiO₂ as an oxide. SANOS includes poly-Si as a gate electrode, SiO₂ as an oxide and Al₂O₃ as a blocking oxide layer (Chin-Yuan Lu et al. Non-volatile memory technology—Today and Tomorrow, Proceedings of 13^{th} IPFA 2006, Singapore).

SONOS, SANOS, and TANOS structures having a gate-a blocking oxide-a charge trapping layer-a tunnel oxide layer-a substrate are evolved in order to solve the problems of the conventional floatin gate in a nonvolatile flash memory.

To this end, the composition incorporating apparatus of FIG. 3 includes a plasma generating chamber, three grids that sequentially overlap each other, and a reflector. Here, the ion beams are accelerated by applying a positive voltage to the first grid, the uppermost grid, of the three grids, which is adjacent to the plasma generating chamber, and an optical axis of each beam is adjusted by applying a negative voltage to the second grid, the intermediate grid. Further, the third grid, the lowermost grid, and the reflector are grounded to convert the extracted ion beams to the neutral beams, so that the electrical damage to the target substrate is minimized.

Further, in the present invention, an available gas includes nitrogen series, oxygen series, CₓF_{y} series, fluorine series, and so on. The target substrate 16 is formed of high dielectric constant materials, i.e. high-k materials, such as Al₂O₃, HfO₂, TiO₂, ZrO₂, Y₂O₃, Ta₂O₅, and La₂O₃ including SiO₂.

According to the present invention, the grid assembly and the reflector 15, which are located under the ion source 11, are in close contact with each other, so that the ion beams 11a can be prevented from being leaked in an undesired direction, thus remarkably reducing contamination. Thereby, neutron flux of the neutral beams 11b may be considerably increased. Further, since a space occupied by the reflector 15 may be reduced. As a result, the composition incorporating apparatus 10 may be made small and inexpensive.

The ion beams may be accelerated by voltage application. The grid assembly having the plurality of grid holes through which the ion beams can pass is disclosed in Korean Patent No. 0380660, granted to the present applicant, and so the description thereof will be omitted.

Now, a method of processing the target substrate, the wafer, using the composition incorporating apparatus illustrated in FIG. 3 will be described.

A gas for generating the ion beams is injected through an ion beam generating gas inlet, which is not shown. Then, the ion gas, which is injected through the ion beam generating gas inlet, is generated to the ion beams having a polarity by the ion source 11. The generated ion beams 11 pass through the grid assembly 14 and the reflector 15, and then are converted to the neutral beams. The neutral beams are applied to the target substrate 16, and process the target wafer 16.

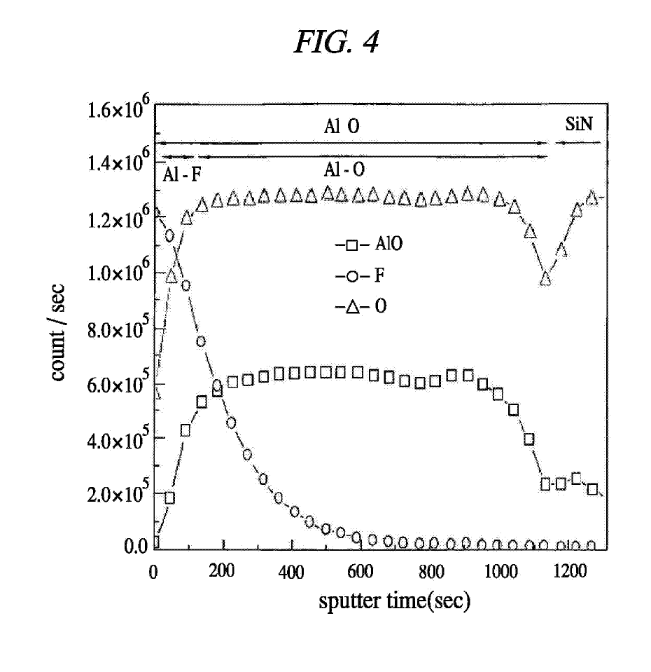

FIG. 4 is a graph showing the results obtained by measuring a change in the depth profile of an oxide layer using secondary ion mass spectrometry (SMIS) after a target substrate is subjected to surface treatment by the composition incorporating apparatus illustrated in FIG. 3. Here, Al₂O₃ was processed by the neutral beams having low energy, and then a depth profile was measured using the SIMS. As a result, it could be found that the neutral beam processing of Al₂O₃ formed Al—F bonds to thereby improve characteristics of the oxide layer.

Further, in the apparatus for processing a surface of a substrate using neutral beams according to the present invention, in order to improve the characteristics of the oxide layer, i.e., the target layer deposited on the target substrate, neutral beams having a low energy below 100 eV are used such that there is almost no change in thickness of the oxide layer.

Preferably, the oxide layer of the target substrate is processed by neutral beams having an energy of 10 eV so as to minimize electrical damage to the oxide layer.

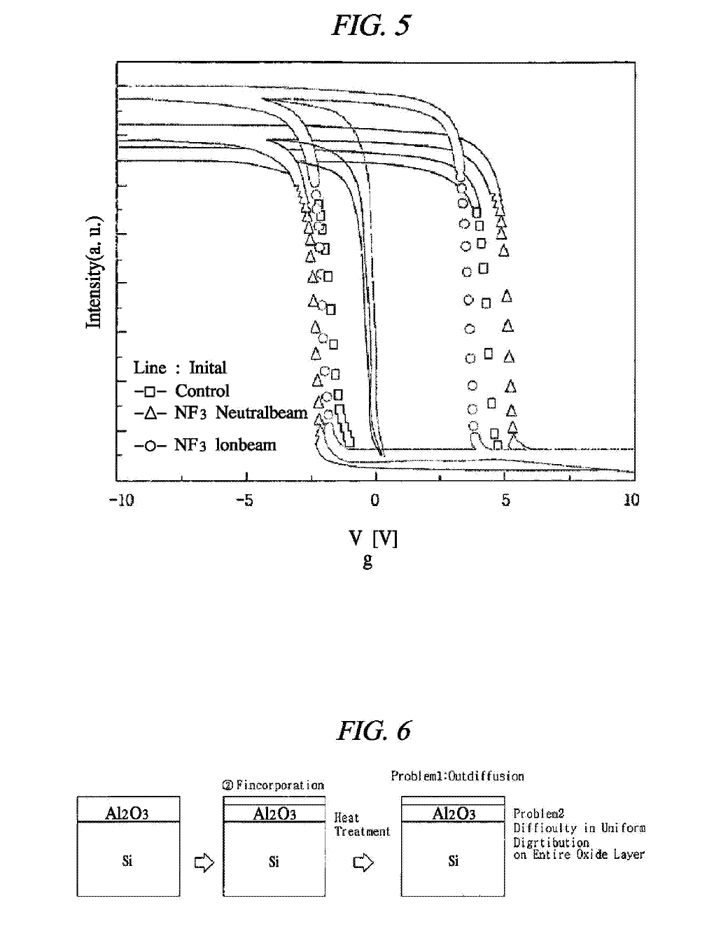

FIG. 5 is a graph showing characteristics of a memory device fabricated using an apparatus for processing a surface of a substrate using neutral beams according to the present invention. As shown in FIG. 5, neutral beams are applied to the oxide layer deposited on the target substrate using the apparatus for processing a surface of a substrate using neutral beams according to the present invention.

The C-V characteristics of the MOS devices described above were also measured, and the results are shown in Figure. The C-V characteristics of the MOS devices showed a hystesis curve (related to the memory window characteristics) within the voltage range of −15˜15 V, due to the charge trapping between Si₃N₄ and Al₂O₃ in the ONA layers. As shown in the C-V hysteresis curve, the MOS device fabricated with the F-neutral-beam-treated ONA layer showed the widest memory window characteristics due to the increase in its charge-trapping characteristics. When the C-V characteristics of the MOS device fabricated with the F-neutral-beam-treated ONA layer were compared with those of the MOS device fabraicated with the untreated ONA layer, the charge-trapping characteristics related to electron trappling were found to have been significantly improved for the MOS device fabricated with the F-neutral-beam-treated ONA layer. This is believed to be related to the effective electron blocking by the Al—F layer formed on the surface of the Al2O3 without causing any charge-related damage. In the case of the C-V characteristics of the MOS device fabricated with the F-ion-beam-treated ONA layer, the memory window was also improved compared with that of the MOS device fabricated with the untreated ONA layer, due to the Al—F layer formed on the Al₂O₃. The memory window, however, was narrower than that of the MOS device fabricated with the F-neutral-beam-treated ONA layer. Moreover, the improvement of the memory window was related to hole trapping rather than to electron trappling, which might be due to the positive-charge-related damage during the F ion bombardment. The charge-related damage to the ONA layer during the F ion beam treatment needs to be investigated in detail, but the significant differences in the characteristics of the MOS device due to the charging of the ONA layer were confirmed by measuring the C-V characteristics of the MOS devices, and a significant improvement of the memory characteristics of the MOS device fabricated with the F-neutral-beam-treated ONA layer was observed.

At this time, the neutral beams are applied to the oxide layer with a low energy of 10 eV or less such that the oxide layer deposited on the target substrate does not undergo electrical damage, i.e. such that the oxide layer deposited on the target substrate is not etched, thereby incorporating the composition into the target substrate.

In this case, it will be seen from FIG. 5 that characteristics of the memory device including the oxide layer is improved.

FIG. 6 illustrates a conventional process of processing a substrate using neutral beams. As illustrated in FIG. 6, in the conventional process of processing a target substrate using neutral beams, the neutral beam is applied only to the top surface of the oxide layer, and thus neutral ionic species incorporated to the target substrate are diffused to the outside of the oxide layer through post treatment such as heat treatment.

Thus, the neutral ionic species are lost by the diffused amount. Simultaneously, the neutral beams are not uniformly applied to the overall target substrate, so that a uniform oxide layer cannot be formed.

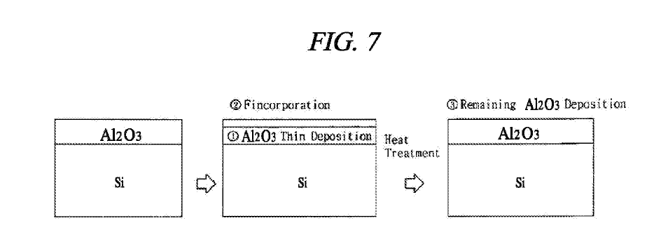

FIG. 7 is a schematic cross-sectional view illustrating a process of forming an oxide layer on a target substrate, and a process of applying neutral beams to the oxide layer using an apparatus for processing a surface of a substrate using neutral beams according to the present invention. As illustrated in FIG. 7, both the process of forming the oxide layer on the target substrate and the process of applying neutral beams to the oxide layer are performed at least twice.

More specifically, as illustrated in FIG. 7, the process of depositing a predetermined amount of Al₂O₃ to form a thin oxide layer and the process of applying neutral beams to the oxide layer are repeated. Then, when heat treatment is performed, the remaining amount of Al₂O₃ is deposited. These processes are performed at least twice when the thickness of the oxide layer reaches the half of a desired thickness or at a desired position of the oxide layer.

Thus, when the oxide layer is processed twice or more as in the present invention, the neutral ionic species can be uniformly distributed throughout the oxide layer after post treatment such as heat treatment.

As described above, an apparatus and method for processing a surface of a substrate using neutral beams according to the present invention can improve equipment and process technology that may be generally used for a next-generation semiconductor device such as a tantalium-aluminium oxide-nitride-oxide-silicon (TANOS) device, a silicon-oxide-nitride-oxide-silicon (SONOS) device, and so on.

Further, in the apparatus and method for processing a surface of a substrate using neutral beams according to the present invention, the surface treatment is repeatedly performed on the oxide layer of the semiconductor device using ions, which are generated from the composition incorporating apparatus, i.e. the neutral beam generator so as to have a low energy of 10 eV or less, so that electrical damage to the oxide layer can be minimized. In order words, the ions of O, N, F, or so on are incorporated into the oxide layer, so that electrical characteristics of the oxide layer can be improved.

In this manner, the present invention is directed to improve the electrical characteristics of the oxide layer using the neutral beams. At this time, the use of the neutral beams can prevent electrical damage to the oxide layer, which may occur in an existing method using plasma, so that the characteristics of the oxide layer can be improved. Particularly, when the neutral beams are applied to a gate oxide layer of the semiconductor device, the electrical characteristics of the oxide layer may be prevented from being degraded by plasma damage, which may occur in the existing method.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A method of processing a surface of a substrate using neutral beams, comprising the steps of:
(a) forming an oxide layer on the substrate;
(b) applying the neutral beams to the oxide layer to incorporate at least one of O, N and F elements into the oxide layer; and
wherein the neutral beams are generated through the steps of:
injecting a gas including at least one of O₂, N₂, C_{X}F_{Y} (where x=1 to 4, y=2 to 8) and NF₃ for generating ion beams through an inlet into an ion source;
generating the ion beams having a polarity from the injected gas in the ion source; and
converting the ion beams into the neutral beams containing at least one of O, N and F elements.

2. The method of claim 1, wherein the step (a) and (b) are repeated at least one time.

3. The method of claim 1, wherein the substrate is formed of SiO₂.

4. The method of claim 1, wherein the substrate is formed of Al₂O₃, HfO₂, TiO₂, ZrO₂, Y₂O₃, Ta₂O₅, BeO or La₂O₃.

5. The method of claim 4, wherein one of a SONOS (silicon-oxide-nitride-oxide-silicon) structure, a TANOS (tantalium-aluminium oxide-nitride-oxide-silicon) structure, or a SANOS (silicon-aluminium oxide-nitride-oxide-silicon) structure is formed on the substrate.

6. The method of claim 1, wherein the neutral beams have an energy below 100 eV.

7. The method of claim 1, wherein the neutral beams have the energy of 10 eV

8. The method of claim 3, wherein one of a SONOS (silicon-oxide-nitride-oxide-silicon) structure, a TANOS (tantalium-aluminium oxide-nitride-oxide-silicon) structure, or a SANOS (silicon-aluminium oxide-nitride-oxide-silicon) structure is formed on the substrate.
